(19) United States
(12) Patent Application Publication
(10) Pub. No.: US 2025/0038734 A1
(43) Pub. Date: Jan. 30, 2025

(54) METAL LAYER BETWEEN ELECTRODES AND PIEZOELECTRIC LAYER FOR CONTROLLING COUPLING

(71) Applicant: Murata Manufacturing Co., Ltd., Nagaokakyo-shi (JP)

(72) Inventor: John P. KOULAKIS, Los Angeles, CA (US)

(21) Appl. No.: 18/775,010

(22) Filed: Jul. 17, 2024

Related U.S. Application Data
(60) Provisional application No. 63/529,220, filed on Jul. 27, 2023.

(51) Int. Cl. H03H 9/13; H03H 3/02; H03H 9/02; H03H 9/17; H03H 9/56

(52) U.S. Cl. CPC H03H 9/132; H03H 3/02; H03H 9/02228; H03H 9/173; H03H 9/564; H03H 9/568; H03H 2003/021

(57) ABSTRACT

An acoustic resonator device is provided that a piezoelectric layer; an interdigital transducer on a surface of the piezoelectric layer and including interleaved IDT fingers extending from first and second busbars respectively; and a metal layer disposed between a finger of the interleaved IDT fingers and the piezoelectric layer in a thickness direction that is measured in a direction normal to the surface of the piezoelectric layer. In this aspect, a ratio of a width of the metal layer to a pitch of the interleaved IDT fingers is greater than or equal to 0.45, the width of the metal layer being measured in a width direction that is parallel to the surface of the piezoelectric layer. Moreover, a thickness of the metal layer in the thickness direction is less than one third a thickness of the finger in the thickness direction.

### TECHNICAL FIELD

This present application claims priority to U.S. Patent Provisional Application No. 63/529,220, filed Jul. 27, 2023, the entire contents of which are hereby incorporated by reference.

### TECHNICAL FIELD

This disclosure relates to radio frequency filters using acoustic wave resonators, and specifically to acoustic waver resonators and filters for use in communications equipment and having metal layers between electrodes and piezoelectric layers for controlled coupling.

### BACKGROUND

A radio frequency (RF) filter is a two-port device configured to pass some frequencies and to stop other frequencies, where “pass” means transmit with relatively low signal loss and “stop” means block or substantially attenuate. The range of frequencies passed by a filter is referred to as the “pass-band” of the filter. The range of frequencies stopped by such a filter is referred to as the “stop-band” of the filter. A typical RF filter has at least one pass-band and at least one stop-band. Specific requirements on a pass-band or stop-band depend on the specific application. For example, a “pass-band” may be defined as a frequency range where the insertion loss of a filter is better than a defined value such as 1 dB, 2 dB, or 3 dB. A “stop-band” may be defined as a frequency range where the rejection of a filter is greater than a defined value such as 20 dB, 30 dB, 40 dB, or greater depending on application.

RF filters are used in communications systems where information is transmitted over wireless links. For example, RF filters may be found in the RF front-ends of cellular base stations, mobile telephone and computing devices, satellite transceivers and ground stations, IoT (Internet of Things) devices, laptop computers and tablets, fixed point radio links, and other communications systems. RF filters are also used in radar and electronic and information warfare systems.

Performance enhancements to the RF filters in a wireless system can have a broad impact to system performance. Improvements in RF filters can be leveraged to provide system performance improvements such as larger cell size, longer battery life, higher data rates, greater network capacity, lower cost, enhanced security, higher reliability, etc. These improvements can be realized at many levels of the wireless system both separately and in combination, for example at the RF module, RF transceiver, mobile or fixed sub-system, or network levels. As the demand for RF filters operating at higher frequencies continues to increase, there is a need for improved filters that can operate at different frequency bands while also improving the manufacturing processes for making such filters.

The Transversely-Excited Film Bulk Acoustic Resonator (XBAR) is an acoustic resonator structure for use in microwave filters. An XBAR resonator comprises an interdigital transducer (IDT) formed on a thin floating layer, or diaphragm, of a single-crystal piezoelectric material. The IDT includes a first set of parallel fingers, extending from a first busbar and a second set of parallel fingers extending from a second busbar. The first and second sets of parallel fingers are interleaved. A microwave signal applied to the IDT excites a shear primary acoustic wave in the piezoelectric diaphragm. XBAR resonators provide very high electromechanical coupling and high frequency capability. XBAR resonators may be used in a variety of RF filters including band-reject filters, band-pass filters, duplexers, and multiplexers. XBARs are well suited for use in filters for communications bands with frequencies above 3 GHz.

However, in order to provide the type of high-level performance required by the above-described communications applications, resonator coupling is an important parameter that requires tuning within a narrow range for optimal filter design. Resonator coupling is a measure of separation between the resonance and anti-resonance frequencies of a resonator.

If the coupling of a resonator in a filter is smaller than required by the design parameters of the filter, the desired bandwidth of the filter cannot be achieved. On the other hand, if the coupling of the resonator is larger than required by the design parameters of the filter, selectivity of the filter will decrease.

Various resonator parameters affect coupling, including crystal cut, dielectric thickness above and below the piezoelectric layer, the pitch of the IDT fingers, and the mark of the IDT fingers. However, because modulation of these parameters also affects other important resonator characteristics, such as resonance frequency and spur location and amplitude, these parameters cannot be used to independently tune resonator coupling without affecting other resonator properties.

### SUMMARY

In view of the foregoing, a resonator structure that allows independent tuning of resonator coupling while minimizing changes to other resonator properties would improve the performance of XBAR devices and, by extension, improve the performance of the filters that include such devices.

Thus, in an exemplary aspect, an acoustic resonator device is provided that includes a piezoelectric layer; an interdigital transducer (IDT) on a surface of the piezoelectric layer, the IDT including interleaved IDT fingers extending from first and second busbars respectively; and a metal layer disposed between a finger of the interleaved IDT fingers and the piezoelectric layer in a thickness direction that is measured in a direction normal to the surface of the piezoelectric layer. According to the exemplary aspect, a ratio of a width of the metal layer to a pitch of the interleaved IDT fingers is greater than or equal to 0.45, the width of the metal layer being measured in a width direction that is parallel to the surface of the piezoelectric layer. Moreover, a thickness of the metal layer in the thickness direction is less than one third a thickness of the finger in the thickness direction.

In another exemplary aspect, the acoustic resonator device further comprises a substrate; and a dielectric layer having a cavity disposed therein. In this aspect, the piezoelectric layer is on the dielectric layer and includes a portion that forms a diaphragm that is over the cavity in the dielectric layer.

In another exemplary aspect of the acoustic resonator device, the width of the metal layer is greater than a width of each of the interleaved IDT fingers measured in the width direction, and the finger is positioned centrally in the width direction with respect to the metal layer, such that the metal layer extends beyond two opposing sides of the finger in the width direction.

In another exemplary aspect of the acoustic resonator device, the thickness of the metal layer in the thickness direction is less than 20 nanometers.

In another exemplary aspect of the acoustic resonator device, the thickness of the metal layer in the thickness direction is less than 10% of a thickness of the piezoelectric layer in the thickness direction.

In another exemplary aspect of the acoustic resonator device, the metal layer comprises a first metal layer and a second metal layer, the first metal layer is positioned closer in the thickness direction to the piezoelectric layer than the second metal layer and has a higher adhesion than an adhesion of the second metal layer, and the second metal layer is in contact with the finger of the interleaved IDT fingers and has a higher conductivity to the finger of the interleaved IDT fingers than the first metal layer. Moreover, the first metal layer can be titanium and the second metal layer can be aluminum.

In another exemplary aspect of the acoustic resonator device, the ratio of the width of the metal layer to the pitch of the interleaved IDT fingers is less than 1.0. Moreover, the ratio of the width of the metal layer to the pitch of the interleaved IDT fingers can be greater than or equal to 0.45 and less than 1.0, where the ratio corresponds to a desired coupling between a resonance frequency and an anti-resonance frequency of the acoustic resonator device.

In another exemplary aspect of the acoustic resonator device, the piezoelectric layer is a lithium niobate plate having Euler angles that are [0, 30, 0].

In another exemplary aspect of the acoustic resonator device, the IDT is configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved IDT fingers.

In yet another exemplary aspect, a filter device is provided that includes a plurality of bulk acoustic wave resonators, with at least one of the plurality of bulk acoustic wave resonators comprising a piezoelectric layer; an interdigital transducer (IDT) on a surface of the piezoelectric layer, the IDT including interleaved IDT fingers extending from first and second busbars respectively; and a metal layer disposed between a finger of the interleaved IDT fingers and the piezoelectric layer in a thickness direction that is measured in a direction normal to the surface of the piezoelectric layer. In this aspect, a ratio of a width of the metal layer to a pitch of the interleaved IDT fingers is greater than or equal to 0.45, the width of the metal layer being measured in a width direction that is parallel to the surface of the piezoelectric layer. Moreover, a thickness of the metal layer in the thickness direction is less than one third a thickness of the finger in the thickness direction.

In yet another exemplary aspect, a radio frequency module is provide that includes a filter device including plurality bulk acoustic resonators connected in parallel; and a radio frequency circuit coupled to the filter device, the filter device and the radio frequency circuit being enclosed within a common package. In this aspect, at least one bulk acoustic resonator of the filter device includes a piezoelectric layer; an interdigital transducer (IDT) on a surface of the piezoelectric layer, the IDT including interleaved IDT fingers extending from first and second busbars respectively; and a metal layer disposed between a finger of the interleaved IDT fingers and the piezoelectric layer in a thickness direction that is measured in a direction normal to the surface of the piezoelectric layer. Moreover, a ratio of a width of the metal layer to a pitch of the interleaved IDT fingers is greater than or equal to 0.45, the width of the metal layer being measured in a width direction that is parallel to the surface of the piezoelectric layer. Yet further, a thickness of the metal layer in the thickness direction is less than one third a thickness of the finger in the thickness direction.

The above simplified summary of example aspects serves to provide a basic understanding of the present disclosure. This summary is not an extensive overview of all contemplated aspects and is intended to neither identify key or critical elements of all aspects nor delineate the scope of any or all aspects of the present disclosure. Its sole purpose is to present one or more aspects in a simplified form as a prelude to the more detailed description of the disclosure that follows. To the accomplishment of the foregoing, the one or more aspects of the present disclosure include the features described and exemplary pointed out in the claims.

### BRIEF DESCRIPTION OF THE DRAWINGS

The accompanying drawings, which are incorporated into and form a part of this specification, illustrate one or more example aspects of the present disclosure and, together with the detailed description, serve to explain their principles and implementations.

FIG. 1A includes a schematic plan view and a schematic cross-sectional view of a transversely-excited film bulk acoustic resonator (XBAR).

FIG. 1B shows a schematic cross-sectional view of an alternative configuration of an XBAR.

FIG. 2A is an expanded schematic cross-sectional view of a portion of the XBAR of FIG. 1A.

FIG. 2B is an expanded schematic cross-sectional view of an alternative configuration of the XBAR of FIG. 1A.

FIG. 2C is an expanded schematic cross-sectional view of another alternative configuration of the XBAR of FIG. 1A.

FIG. 2D is an expanded schematic cross-sectional view of another alternative configuration of the XBAR of FIG. 1A.

FIG. 2E is an expanded schematic cross-sectional view of a portion of a solidly-mounted XBAR (SM XBAR).

FIG. 3A is a schematic cross-sectional view of an XBAR according to an exemplary aspect.

FIG. 3B is an alternative schematic cross-sectional view of an XBAR according to an exemplary aspect.

FIG. 4 is a graphic illustrating a shear horizontal acoustic mode in an XBAR.

FIG. 5A is a schematic block diagram of a filter using XBARs of FIGS. 1A and/or 1B.

FIG. 5B is a schematic diagram of a radio frequency module that includes an acoustic wave filter device according to an exemplary aspect.

FIG. 6 is a schematic cross-sectional view of two XBARs illustrating a frequency-setting dielectric layer.

FIG. 7 is a cross-section view of an XBAR with metal pedestal-like layers between each IDT finger and the piezoelectric layer.

FIG. 8 is a graph showing the effect on coupling of different values of the ratio between the width of the metal pedestal-like layers and the pitch of the IDT fingers.

FIG. 9 are graphs showing the shift of anti-resonance frequency with an increased ratio between the width the metal pedestal-like layers and the pitch of the IDT fingers and the resulting frequency bands between the resonance and anti-resonance frequencies.

FIG. 10 is a flow chart of a method for fabricating an XBAR or a filter using XBARs.

Throughout this description, elements appearing in figures are assigned three-digit or four-digit reference designators, where the two least significant digits are specific to the element and the one or two most significant digits are the figure number where the element is first introduced. An element that is not described in conjunction with a figure may be presumed to have the same characteristics and function as a previously-described element having the same reference designator.

### DETAILED DESCRIPTION

Various aspects of the disclosed bulk acoustic resonator, a filter device, a radio frequency module, and method of manufacturing the same are now described with reference to the drawings, wherein like reference numerals are used to refer to like elements throughout. In the following description, for purposes of explanation, numerous specific details are set forth in order to promote a thorough understanding of one or more aspects of the disclosure. It may be evident in some or all instances, however, that any aspects described below can be practiced without adopting the specific design details described below. In other instances, well-known structures and devices are shown in block diagram form in order to facilitate description of one or more aspects. The following presents a simplified summary of one or more aspects of the invention in order to provide a basic understanding thereof.

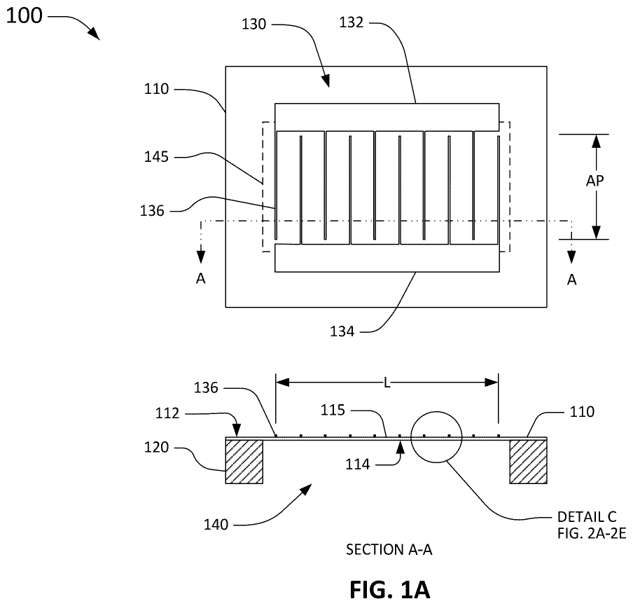

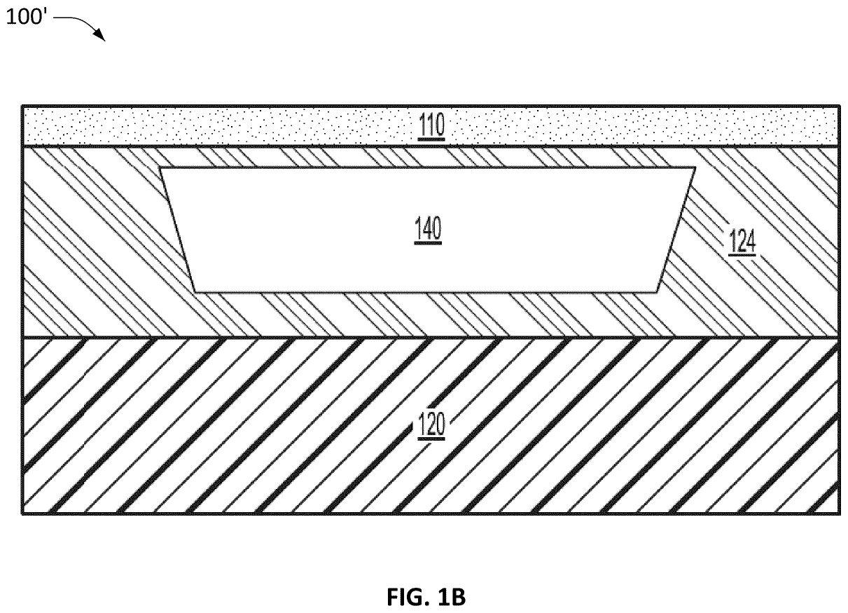

FIG. 1A shows a simplified schematic top view and an orthogonal cross-sectional view of a bulk acoustic resonator device, namely a transversely excited film bulk acoustic resonator (XBAR) 100. XBAR resonators, such as the resonator 100, may be used in a variety of RF filters including band-rejection filters, bandpass filters, duplexers, and multiplexers. XBARs are particularly suited for use in filters for communications bands with frequencies above 3 GHz.

In general, the XBAR 100 includes a conductor pattern (e.g., a thin film metal layer) formed at one or both surfaces of a piezoelectric layer 110 (herein piezoelectric plate or piezoelectric layer may be used interchangeably) having parallel front side 112 and a back side 114, respectively (also referred to generally first and second surfaces, respectively). It should be appreciated that the term “parallel” generally refers to the front side 112 and back side 114 being opposing to each other and that the surfaces are not necessarily planar and exactly parallel to each other. For example, due to the manufacturing variances result from the deposition process, the front side 112 and back side 114 may have undulations of the surface as would be appreciated to one skilled in the art. Moreover, the term “substantially” as used herein is used to describe when components, parameters and the like are generally the same (i.e., “substantially constant”), but may vary slightly (e.g., within an acceptable threshold or percentage) in practice due to possible manufacturing variances as would be appreciated to one skilled in the art. For purposes of this disclosure, the use of the term “or” in the claims is used to mean “and/or” unless explicitly indicated to refer to alternatives only or if the alternatives are mutually exclusive.

According to an exemplary aspect, the piezoelectric layer can be a thin single-crystal layer of a piezoelectric material, such as lithium niobate, lithium tantalate, lanthanum gallium silicate, gallium nitride, or aluminum nitride. It should be appreciated that the term “single-crystal” does not necessarily mean entirely of a uniform crystalline structure and may include impurities due to manufacturing variances as long as the crystal structure is within acceptable tolerances. The piezoelectric layer is cut such that the orientation of the X, Y, and Z crystalline axes with respect to the front and back sides is known and consistent. In the examples described herein, the piezoelectric layers are Z-cut, which is to say the Z axis is normal to the front and back sides 112, 114. However, XBARs may be fabricated on piezoelectric layers with other crystallographic orientations including rotated Z-cut, Y-cut and rotated YX cut.

The Y-cut family, such as 120Y and 128Y, are typically referred to as 120YX or 128YX, where the “cut angle” is the angle between the y axis and the normal to the layer. The “cut angle” is equal to β+90°. For example, a layer with Euler angles [0°, 30°, 0°] is commonly referred to as “120° rotated Y-cut” or “120Y.” Thus, the Euler angles for 120YX and 128YX are (0, 120-90,0) and (0, 128-90,0) respectively. A “Z-cut” is typically referred to as a ZY cut and is understood to mean that the layer surface is normal to the Z axis but the wave travels along the Y axis. The Euler angles for ZY cut are (0, 0, 90).

The back side 114 of the piezoelectric layer 110 may be at least partially supported by a surface of the substrate 120 except for a portion of the piezoelectric layer 110 that forms a diaphragm 115 that is over (e.g., spanning or extending over) a cavity 140 in one or more layers below the piezoelectric layer 110 such as one or more intermediate layers above or in the substrate. In other words, the back side 114 of the piezoelectric layer 110 can be coupled or connected either directly or indirectly, via one or more intermediate layers (e.g., a dielectric layer, such as a silicon oxide layer), to a surface of the substrate 120. Moreover, the phrase “supported by” or “attached” may, as used herein interchangeably, mean attached directly, attached indirectly, mechanically supported, structurally supported, or any combination thereof. The portion of the piezoelectric layer that is over (e.g., spanning or extending over) the cavity can be referred to herein as a “diaphragm” 115 due to its physical resemblance to the diaphragm of a microphone. As shown in FIG. 1A, the diaphragm 115 is contiguous with the rest of the piezoelectric layer 110 around all of a perimeter 145 of the cavity 140. In this context, “contiguous” means “continuously connected without any intervening item”. However, the diaphragm 115 can be configured with at least 50% of the edge surface of the diaphragm 115 coupled to the edge of the piezoelectric layer 110 in an exemplary aspect.

According to the exemplary aspect, the substrate 120 is configured to provide mechanical support to the piezoelectric layer 110. The substrate 120 may be, for example, silicon, sapphire, quartz, or some other material or combination of materials. The back side 114 of the piezoelectric layer 110 may be bonded to the substrate 120 using a wafer bonding process. Alternatively, the piezoelectric layer 110 may be grown on the substrate 120 or supported by, or attached to, the substrate in some other manner.

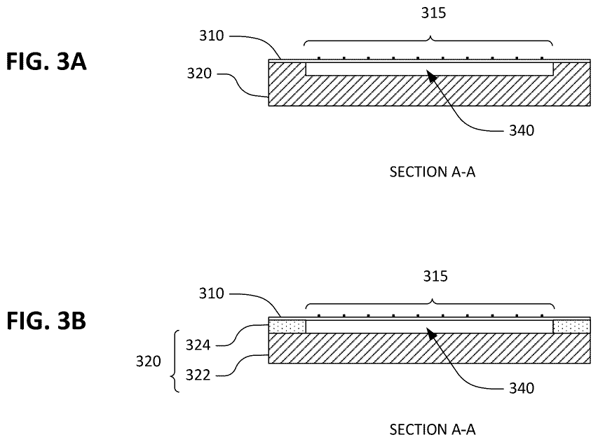

For purposes of this disclosure, “cavity” has its conventional meaning of “an empty space within a solid body.” The cavity 140 may be a hole completely through the substrate 120 (as shown in Section A-A and Section B-B) or a recess in the substrate 120 (as shown subsequently in FIG. 3A and FIG. 3B). The cavity 140 may be formed, for example, by selective etching of the substrate 120 before or after the piezoelectric layer 110 and the substrate 120 are attached, either directly or indirectly.

As shown, the conductor pattern of the XBAR 100 includes an interdigital transducer (IDT) 130. The IDT 130 includes a first plurality of parallel fingers, such as finger 136, extending from a first busbar 132 and a second plurality of fingers extending from a second busbar 134. The first and second pluralities of parallel fingers are interleaved with each other that can be “substantially” parallel to each other due to minor variations, such as due to manufacturing tolerances, for example. At least a portion of the interleaved fingers overlap for a distance AP, commonly referred to as the “aperture” of the IDT. The center-to-center distance L between the outermost fingers of the IDT 130 is the “length” of the IDT.

In the examples of FIGS. 1A-1B, FIG. 3A. and FIG. 3B, the IDT 130 is on the front surface 112 (e.g., the first surface) of the piezoelectric layer 110. However, as discussed below, in other configurations, the IDT 130 may be at the surface of the back side 114 (e.g., the second surface) of the piezoelectric layer 110 or at both the surfaces of the front and back sides 112, 114 of the piezoelectric layer 110, respectively.

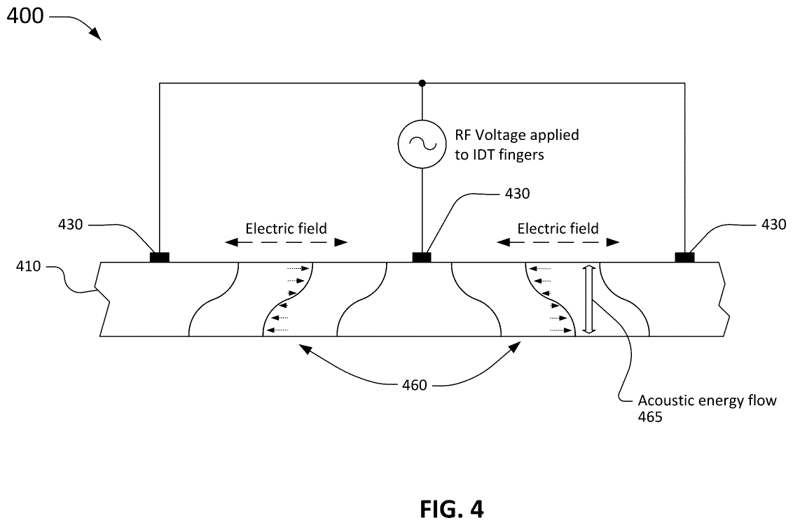

The first and second busbars 132, 134 are configured as the terminals of the XBAR 100 with the plurality of interleaved fingers extending therefrom. In operation, a radio frequency signal or microwave signal applied between the two busbars 132, 134 of the IDT 130 primarily excites an acoustic mode (i.e., a primarily shear acoustic mode) within the piezoelectric layer 110. As will be discussed in further detail, the primarily excited shear acoustic mode is a bulk shear mode or bulk acoustic wave where acoustic energy of a bulk shear acoustic wave is excited in the piezoelectric layer 110 by the IDT 130 and propagates along a direction substantially, predominantly, and/or primarily orthogonal to the surface of the piezoelectric layer 110, which is also primarily normal, or transverse, to the direction of the electric field created by the IDT fingers. That is, when a radio frequency or a microwave signal is applied between the two busbars 132, 134, the RF voltage applied to the respective sets of IDT fingers generates a time-varying electric field that is laterally excited with respect to a surface of the piezoelectric layer 110. Thus, in some cases the primarily excited acoustic mode may be commonly referred to as a laterally excited bulk acoustic wave since displacement, as opposed to propagation, occurs primarily in the direction of the bulk of the piezoelectric layer, as discussed in more detail below in reference to FIG. 4

For purposes of this disclosure, “primarily acoustic mode” may generally refer to an operational mode in which a vibration displacement is caused in the primarily thickness-shear direction (e.g., X-direction), so the wave propagates substantially and/or primarily in the direction connecting the opposing front and back surfaces of the piezoelectric layer, that is, in the Z direction. In other words, the X-direction component of the wave is significantly smaller than the Z-direction component. The use of the term “primarily” in the “primarily excited acoustic mode” is not necessarily referring to a lower or higher order mode. Thus, the XBAR is considered a transversely excited film bulk wave resonator. One physical constraint is that when the radio frequency or microwave signal is applied between the two busbars 132, 134 of the IDT 130, heat is generated that must be dissipated from the resonator for improved performance. In general, heat can be dissipated by lateral conduction on the membrane (e.g., in the electrodes themselves), and vertical conduction through a cavity to substrate.

In any event, the IDT 130 is positioned at or on the piezoelectric layer 110 such that at least the fingers of the IDT extend at or on the portion of the piezoelectric layer 110 that is over the cavity 140, for example, the diaphragm 115 as described herein. As shown in FIG. 1A, the cavity 140 has a rectangular cross section with an extent greater than the aperture AP and length L of the IDT 130. According to other exemplary aspects, the cavity of an XBAR may have a different cross-sectional shape, such as a regular or irregular polygon. The cavity of an XBAR may have more or fewer than four sides, which may be straight or curved.

According to an exemplary aspect, the area of XBAR 100 is determined as the area of the IDT 130. For example, the area of the IDT 130 can be determined based on the measurement of the length L multiplied by the width of the aperture AP of the interleaved fingers of the IDT 130. As used herein through the disclosure, area is referenced in μm². Thus, the area of the XBAR 100 may be adjusted based on design choices, as described below, thereby adjusting the overall capacitance of the XBAR 100.

For ease of presentation in FIG. 1A, the geometric pitch and width of the IDT fingers is greatly exaggerated with respect to the length (dimension L) and aperture (dimension AP) of the XBAR. A typical XBAR has more than ten parallel fingers in the IDT. For example, an XBAR may have hundreds, possibly thousands, of parallel fingers in the IDT according to exemplary aspects. Similarly, the thickness of the fingers in the cross-sectional views is greatly exaggerated.

FIG. 1B shows a schematic cross-sectional view of an alternative XBAR configuration 100′. In FIG. 1B, the cavity 140 (which can correspond generally to cavity 140 of FIG. 1A) of the resonator 100′ is formed entirely within a dielectric layer 124 (for example silicon oxide or silicon dioxide, as in FIG. 1B) that is located between the substrate 120 (indicated as Si in FIG. 1B) and the piezoelectric layer 110 (indicated as LN in FIG. 1B). Although a single dielectric layer 124 is shown having cavity 140 formed therein (e.g., by etching), it should be appreciated that the dielectric layer 124 can be formed by a plurality of separate dielectric layers formed on each other to provide a stack of materials.

Moreover, in the example of FIG. 1B, the cavity 140 is defined on all sides by the dielectric layer 124. However, in other exemplary embodiments, one or more sides of the cavity 140 may be defined by the substrate 120 and/or the piezoelectric layer 110. In the example of FIG. 1B, the cavity 140 has a trapezoidal shape. However, as noted above, cavity shape is not limited and may be rectangular, oval, or other shapes.

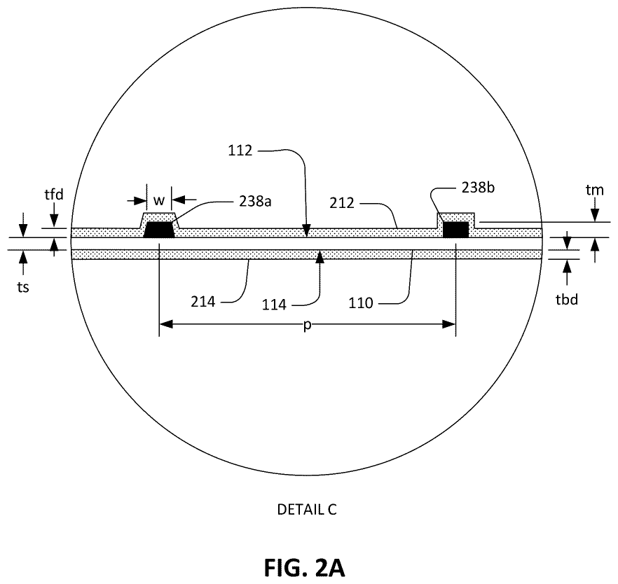

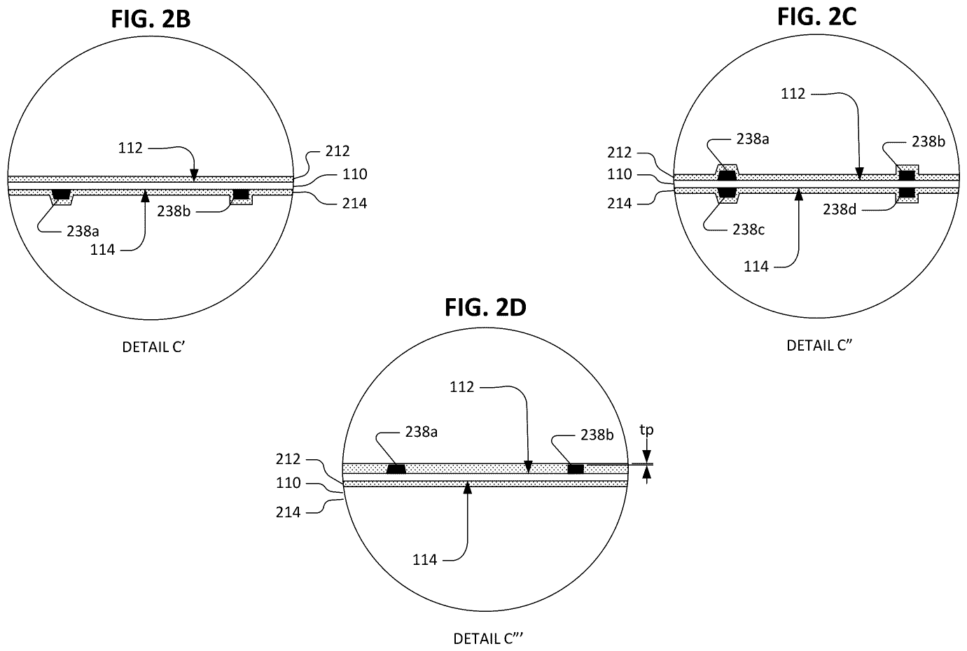

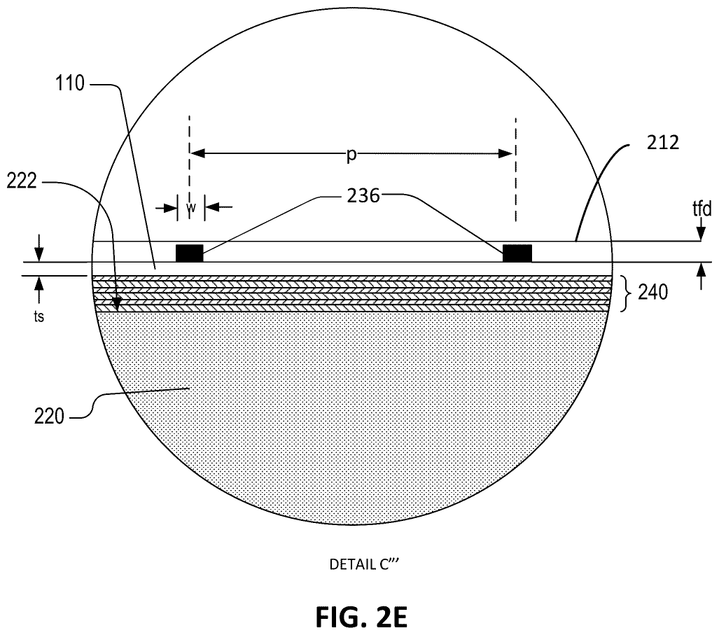

FIG. 2A shows a detailed schematic cross-sectional view (labeled as Detail C) of the XBAR 100 of FIG. 1A or 1B. The piezoelectric layer 110 is a single-crystal layer of piezoelectrical material having a thickness ts. Ts may be, for example, 100 nanometers (nm) to 1500 nm. When used in filters for 5G NR and Wi-Fi™ bands from 3.4 GHZ to 7 GHz, the thickness ts may be, for example, 150 nm to 500 nm. The thickness ts can be measured in a direction substantially perpendicular or orthogonal to a surface of the piezoelectric layer in an exemplary aspect.

In this aspect, a front side dielectric layer 212 (e.g., a first dielectric coating layer or material) can be formed on the front side 112 of the piezoelectric layer 110. The “front side” of the XBAR is, by definition, the surface facing away from the substrate. The front side dielectric layer 212 has a thickness tfd. As shown in FIG. 2A the front side dielectric layer 212 covers the IDT fingers 238a, 238b, which can correspond to fingers 136 as described above with respect to FIG. 1A. Although not shown in FIG. 2A, the front side dielectric layer 212 may also be deposited only between the IDT fingers 238a, 238b. In this case, an additional thin dielectric layer (not shown) may be deposited over the IDT fingers to seal and passivate the fingers. Further, although also not shown in FIG. 2A, the front side dielectric layer 212 may also be deposited only on select IDT fingers 238a, for example.

A back side dielectric layer 214 (e.g., a second dielectric coating layer or material) can also be formed on the back side of the back side 114 of the piezoelectric layer 110. In general, for purposes of this disclosure, the term “back side” means on a side opposite the conductor pattern of the IDT structure and/or opposite the front side dielectric layer 212. Moreover, the back side dielectric layer 214 has a thickness tbd. The front side and back side dielectric layers 212, 214 may be a non-piezoelectric dielectric material, such as silicon oxide, silicon dioxide or silicon nitride. Tfd and tbd may be, for example, 0 to 500 nm. Tfd and tbd may be less than the thickness ts of the piezoelectric layer. Tfd and tbd are not necessarily equal, and the front side and back side dielectric layers 212, 214 are not necessarily the same material. In exemplary aspects, either or both of the front side and back side dielectric layers 212, 214 may be formed of multiple layers of two or more materials according to various exemplary aspects.

The IDT fingers 238a, 238b may comprise aluminum, substantially (i.e., predominantly) aluminum alloys, copper, substantially (i.e., predominantly) copper alloys, beryllium, gold, or some other conductive material. Thin (relative to the total thickness of the conductors) layers of other metals, such as chromium or titanium, may be formed under and/or over the fingers to improve adhesion between the fingers and the piezoelectric layer 110 and/or to passivate or encapsulate the fingers. The busbars (132, 134 in FIG. 1A) of the IDT may be made of the same or different materials as the fingers. The cross-sectional shape of the IDT fingers may be trapezoidal (finger 238a), rectangular (finger 238b) or some other shape in various exemplary aspects. In general, it is noted that the terms “comprise”, “have”, “include” and “contain” (and their variants) as used herein are open-ended linking verbs and allow the addition of other elements when used in a claim. Moreover, the use of the word “a” or “an” when used in conjunction with the term “comprising” in the claims or the specification means one or more than one, unless the context dictates otherwise.

As discussed below, thin metal pedestal-like layers may be formed between the IDT fingers and the piezoelectric layer to tune coupling.

Dimension p (i.e., the “pitch”) can be considered the center-to-center spacing between adjacent IDT fingers, such as the IDT fingers 238a, 238b in FIGS. 2A-2D. Center points of center-to-center spacing may be measured at a center of the width “w” of a finger as shown in FIG. 2A. In some cases, the center-to-center spacing may change if the width of a given finger changes along the length of the finger, if the width and extending direction changes, or any variation thereof. In that case, for a given location along AP, center-to-center spacing may be measured as an average center-to-center spacing, a maximum center-to-center spacing, a minimum center-to-center spacing, or any variation thereof. Adjacent fingers may each extend from a different busbar and center-to-center spacing may be measured from a center of a first finger extending from a first busbar to a center of a second finger, adjacent to the first finger, extending from a second busbar. The center-to-center spacing may be constant over the length of the IDT, in which case the dimension p may be referred to as the pitch of the IDT and/or the pitch of the XBAR. However, in an alternative exemplary aspect, the center-to-center spacing varies along the length of the IDT, in which case the pitch of the IDT may be the average value of dimension p over the length of the IDT. Center-to-center spacing from one finger to an adjacent finger may vary continuously when compared to other adjacent fingers, in discrete sections of multiple adjacent pairs, or any combination thereof. Each IDT finger, such as the IDT fingers 238a, 238b in FIGS. 2A to 2D, has a width w measured normal to the long direction of each finger. The width w may also be referred to herein as the “mark.” In general, the width of the IDT fingers may be constant over the length of the IDT, in which case the dimension w may be the width of each IDT finger. However, in another exemplary aspect as will be discussed below, the width of individual IDT fingers varies along the length of the IDT 130, in which case dimension w may be the average value of the widths of the IDT fingers over the length of the IDT. Note that the pitch p and the width w of the IDT fingers are measured in a direction substantially parallel to the length L of the IDT, as defined in FIG. 1A.

In general, the IDT of an XBAR differs substantially from the IDTs used in surface acoustic wave (SAW) resonators, primarily in that IDTs of an XBAR excite a primary shear acoustic mode (also referred to as a primary shear mode, a primary shear thickness mode, or the like), as described in more detail below with respect to FIG. 4, where SAW resonators excite a surface wave in operation. Moreover, in a SAW resonator, the pitch of the IDT is one-half of the acoustic wavelength at the resonance frequency. Additionally, the mark-to-pitch ratio of a SAW resonator IDT is typically close to 0.5 (i.e., the mark or finger width is about one-fourth of the acoustic wavelength at resonance). In an XBAR, the pitch p of the IDT is typically 2 to 20 times the width w of the fingers. in addition, the pitch p of the IDT is typically 2 to 20 times the thickness ts of the piezoelectric layer 110. Moreover, the width of the IDT fingers in an XBAR is not constrained to one-fourth of the acoustic wavelength at resonance. For example, the width of XBAR IDT fingers may be 500 nm or greater, such that the IDT can be fabricated using optical lithography. The thickness tm of the IDT fingers may be from 100 nm to about equal to the width w, as the lithography process typically cannot support a configuration where the thickness is greater than the width. The thickness of the busbars (132, 134 in FIG. 1A) of the IDT may be the same as, less than, greater than, or any combination thereof, the thickness tm of the IDT fingers. It is noted that the XBAR devices described herein are not limited to the ranges of dimensions described herein.

Moreover, unlike a SAW filter, the resonance frequency of an XBAR is dependent on the total thickness of its diaphragm (i.e., in the vertical or thickness direction), including the piezoelectric layer 110, and the front side and back side dielectric layers 212, 214 disposed thereon. In an exemplary aspect, the thickness of one or both dielectric layers (i.e., on the opposing surfaces of the piezoelectric layer) can be varied to change the resonance frequencies of various XBARs in a filter. For example, shunt resonators in a ladder filter circuit may incorporate thicker dielectric layers to reduce the resonance frequencies of the shunt resonators relative to series resonators with thinner dielectric layers, and thus a thinner overall thickness.

Referring back to FIG. 2A, the thickness tfd of the front side dielectric layer 212 over the IDT fingers 238a, 238b may be greater than or equal to a minimum thickness required to cover and passivate the IDT fingers and other conductors on the front side 112 to the piezoelectric layer 110. The minimum thickness may be, for example, 10 nm to 50 nm depending on the material of the front side dielectric layer and method of deposition according to an exemplary aspect. The thickness of the back side dielectric layer 214 may be configured to a specific thickness to adjust the resonance frequency of the resonator as will be described in more detail below.

Although FIG. 2A discloses a configuration in which IDT fingers 238a and 238b are at the front side 112 of the piezoelectric layer 110, alternative configurations can be provided. For example, FIG. 2B shows an alternative configuration (identified as Detail C′) in which the IDT fingers 238a, 238b are at the back side 114 of the piezoelectric layer 110 (i.e., facing the cavity) and are covered by a back side dielectric layer 214. A front side dielectric layer 212 may cover the front side 112 of the piezoelectric layer 110. In exemplary aspects, a dielectric layer disposed on the diaphragm of each resonator can be trimmed or etched to adjust the resonant frequency. However, if the dielectric layer is on the side of the diaphragm facing the cavity, there may be a change in spurious modes (e.g., generated by the coating on the fingers). Moreover, with the passivation layer coated on top of the IDTs, the mark changes, which can also cause spurs. Therefore, disposing the IDT fingers 238a, 238b at the back side 114 of the piezoelectric layer 110 as shown in FIG. 2B may eliminate addressing both the change in frequency as well as the effect it has on spurs as compared when the IDT fingers 238a and 238b are on the front side 112 of the piezoelectric layer 110.

FIG. 2C shows an alternative configuration (identified as Detail C″) in which IDT fingers 238a, 238b are on the front side 112 of the piezoelectric layer 110 and are covered by a front side dielectric layer 212. IDT fingers 238c, 238d are also on the back side 114 of the piezoelectric layer 110 and are also covered by a back side dielectric layer 214. As previously described, the front side and back side dielectric layer 212, 214 are not necessarily the same thickness or the same material.

FIG. 2D shows another alternative configuration (identified as Detail C′″) in which IDT fingers 238a, 238b are on the front side 112 of the piezoelectric layer 110 and are covered by a front side dielectric layer 212. The surface of the front side dielectric layer is planarized. The front side dielectric layer may be planarized, for example, by polishing or some other method. A thin layer of dielectric material having a thickness tp may cover the IDT finger 238a, 238b to seal and passivate the fingers. The dimension TP may be, for example, 10 nm to 50 nm.

Each of the XBAR configurations described above with respect to FIGS. 2A to 2D include a diaphragm spanning over a cavity. However, in an alternative aspect, the bulk acoustic resonator can be solidly mounted in which the diaphragm with IDT fingers is mounted on or above a Bragg mirror, which in turn can be mounted on a substrate.

In particular, FIG. 2E shows a detailed schematic cross-sectional view of a solidly mounted XBAR (SM-XBAR). It is noted that FIG. 2E generally discloses a similar cross section as that of FIG. 1A, except having a solidly mounted configuration. In this aspect, the SM-XBAR includes a piezoelectric layer 110 and an IDT (of which only two fingers 236 are visible) with a dielectric layer 212 disposed on the piezoelectric layer 110 and IDT fingers 236. The piezoelectric layer 110 has parallel front and back surfaces similar to the configurations described above. Dimension ts is the thickness of the piezoelectric layer 110. The width of the IDT fingers 236 is dimension w, thickness of the IDT fingers is dimension tm, and the IDT pitch is dimension p.

In contrast to the XBAR devices shown in FIG. 1A, the IDT of an SM XBAR in FIG. 2E is not formed on a diaphragm spanning a cavity in the substrate. Instead, an acoustic Bragg reflector 240 is sandwiched between a surface 222 of the substrate 220 and the back surface of the piezoelectric layer 110. The term “sandwiched” means the acoustic Bragg reflector 240 is both disposed between and mechanically attached to a surface 222 of the substrate 220 and the back surface of the piezoelectric layer 110. In some circumstances, layers of additional materials (e.g., one or more dielectric layers) may be disposed between the acoustic Bragg reflector 240 and the surface 222 of the substrate 220 and/or between the Bragg reflector 240 and the back surface of the piezoelectric layer 110. Such additional material layers may be present, for example, to facilitate bonding the piezoelectric layer 110, the acoustic Bragg reflector 240, and the substrate 220.

The acoustic Bragg reflector 240 may be an acoustic mirror configured to reflect at least a portion of the primary acoustic mode excited in the piezoelectric and includes multiple dielectric layers that alternate between materials having high acoustic impedance and materials having low acoustic impedance. The acoustic impedance of a material is the product of the material's shear wave velocity and density. “High” and “low” are relative terms. For each layer, the standard for comparison is the adjacent layers. Each “high” acoustic impedance layer has an acoustic impedance higher than that of both the adjacent low acoustic impedance layers. Each “low” acoustic impedance layer has an acoustic impedance lower than that of both the adjacent high acoustic impedance layers. As discussed above, the primary acoustic mode in the piezoelectric layer of an XBAR is a shear bulk wave. In an exemplary aspect, each layer of the acoustic Bragg reflector 240 has a thickness equal to, or about, one-fourth of the wavelength in the layer of a shear bulk wave having the same polarization as the primary acoustic mode at or near a resonance frequency of the SM XBAR. Dielectric materials having comparatively low acoustic impedance include silicon dioxide, carbon-containing silicon oxide, and certain plastics such as cross-linked polyphenylene polymers. Materials having comparatively high acoustic impedance include hafnium oxide, silicon nitride, aluminum nitride, silicon carbide. All of the high acoustic impedance layers of the acoustic Bragg reflector 240 are not necessarily the same material, and all of the low acoustic impedance layers are not necessarily the same material. In the example of FIG. 2E, the acoustic Bragg reflector 240 has a total of six layers, but an acoustic Bragg reflector may have more than, or less than, six layers in alternative configurations.

The IDT fingers, such as IDT finger 236, 238a, and 238b, may be disposed on a surface of the front side 112 of the piezoelectric layer 110. Alternatively, IDT fingers, such as IDT finger 236, 238a, and 238b, may be disposed in grooves formed in the surface of the front side 112. The grooves may extend partially through the piezoelectric layer. Alternatively, the grooves may extend completely through the piezoelectric layer.

FIG. 3A and FIG. 3B illustrate alternative cross-sectional views along the section plane A-A defined in FIG. 1A. In particular, as shown in FIG. 3A, a piezoelectric layer 310, which corresponds to piezoelectric layer 110, is attached directly to a substrate 320, which can correspond to substrate 120 of FIG. 1A. Moreover, a cavity 340, which does not fully penetrate the substrate 320, is formed in the substrate under the portion (i.e., the diaphragm 315) of the piezoelectric layer 310 containing the IDT of an XBAR. The cavity 340 can correspond to cavity 140 of FIGS. 1A and/or 1B in an exemplary aspect. In an exemplary aspect, the cavity 340 may be formed, for example, by etching the substrate 320 before attaching the piezoelectric layer 310. Alternatively, the cavity 340 may be formed by etching the substrate 320 with a selective etchant that reaches the substrate through one or more openings provided in the piezoelectric layer 310.

FIG. 3B illustrates an alternative aspect in which the substrate 320 includes a base 322 and an intermediate layer 324 that is disposed between the piezoelectric layer 310 and the base 322. For example, the base 322 may be silicon (e.g., a silicon support substrate) and the intermediate layer 324 may be silicon dioxide or silicon nitride or some other material, e.g., an intermediate dielectric layer. That is, in this aspect, the base 322 and the intermediate layer 324 are collectively considered the substrate 320. As further shown, cavity 340 is formed in the intermediate layer 324 under the portion (i.e., the diaphragm 315) of the piezoelectric layer 310 containing the IDT fingers of an XBAR. The cavity 340 may be formed, for example, by etching the intermediate layer 324 before attaching the piezoelectric layer 310. Alternatively, the cavity 340 may be formed by etching the intermediate layer 324. In other example embodiments, the cavity 340 may be defined in the intermediate layer 324 by other means from whether the intermediate layer 324 was etched to define the cavity 340. In some cases, the etching may be performed with a selective etchant that reaches the substrate through one or more openings (not shown) provided in the piezoelectric layer 310.

In this case, the diaphragm 315, which can correspond to diaphragm 115 of FIG. 1A, for example, in an exemplary aspect, may be contiguous with the rest of the piezoelectric layer 310 around a large portion of a perimeter of the cavity 340. For example, the diaphragm 315 may be contiguous with the rest of the piezoelectric layer 310 around at least 50% of the perimeter of the cavity 340. As shown in FIG. 3B, the cavity 340 extends completely through the intermediate layer 324. That is, the diaphragm 315 can have an outer edge that faces the piezoelectric layer 310 with at least 50% of the edge surface of the diaphragm 315 coupled to the edge of the piezoelectric layer 310 facing the diaphragm 315. This configuration provides for increased mechanical stability of the resonator.

In other configurations, the cavity 340 may partially extend into, but not entirely through the intermediate layer 324 (i.e., the intermediate layer 324 may extend over the bottom of the cavity on top of the base 322) or may extend through the intermediate layer 324 and into (either partially or wholly) the base 322. As described above, it should be appreciated that the interleaved fingers of the IDT can be disposed on either or both surfaces of the diaphragm 315 in FIGS. 3A and 3B according to various exemplary aspects.

FIG. 4 is a graphical illustration of the primarily excited acoustic mode of interest in an XBAR. FIG. 4 shows a small portion of an XBAR 400 including a piezoelectric layer 410 and three interleaved IDT fingers 430. In general, the exemplary configuration of XBAR 400 can correspond to any of the configurations described above and shown in FIGS. 2A to 2D and 3A to 3B according to an exemplary aspect. Thus, it should be appreciated that piezoelectric layer 410 can correspond to piezoelectric layer 110 and/or 310 and IDT fingers 430 can be implemented according to any of the configurations of fingers 238a and 238b and/or 338, for example.

In operation, an RF voltage is applied to the interleaved fingers 430. This voltage creates a time-varying electric field between the fingers. The direction of the electric field is lateral (i.e., laterally excited), or primarily parallel to the surface of the piezoelectric layer 410, as indicated by the arrows labeled “electric field.” Due to the high dielectric constant of the piezoelectric layer 410, the electric field is highly concentrated in the piezoelectric layer relative to the air. The lateral electric field introduces shear deformation in the piezoelectric layer 410, and thus strongly excites a shear acoustic mode, in the piezoelectric layer 410. In this context, “shear deformation” is defined as deformation in which parallel planes in a material remain parallel and maintain a constant distance while translating relative to each other. In other words, the parallel planes of material are laterally displaced with respect to each other. A “shear acoustic mode” is defined as an acoustic vibration mode in a medium that results in shear deformation of the medium. The shear deformations in the XBAR 400 are represented by the curves 460, with the adjacent small arrows providing a schematic indication of the direction and magnitude of atomic motion. It is noted that the degree of atomic motion, as well as the thickness of the piezoelectric layer 410, have been exaggerated for ease of visualization in FIG. 4. While the atomic motions are predominantly lateral (i.e., horizontal as shown in FIG. 4), the direction of acoustic energy flow of the primarily excited shear acoustic mode is substantially and/or primarily orthogonal to the surface of the piezoelectric layer, as indicated by the arrow 465.

A bulk acoustic resonator based on shear acoustic wave resonances can achieve better performance than current state-of-the art film-bulk-acoustic-resonators (FBAR) and solidly-mounted-resonator bulk-acoustic-wave (SMR BAW) devices where the electric field is applied in the thickness direction. In such devices, the acoustic mode is compressive with atomic motions and the direction of acoustic energy flow in the thickness direction. In addition, the piezoelectric coupling for shear wave XBAR resonances can be high (>20%) compared to other acoustic resonators. Thus, high piezoelectric coupling enables the design and implementation of microwave and millimeter-wave filters with appreciable bandwidth.

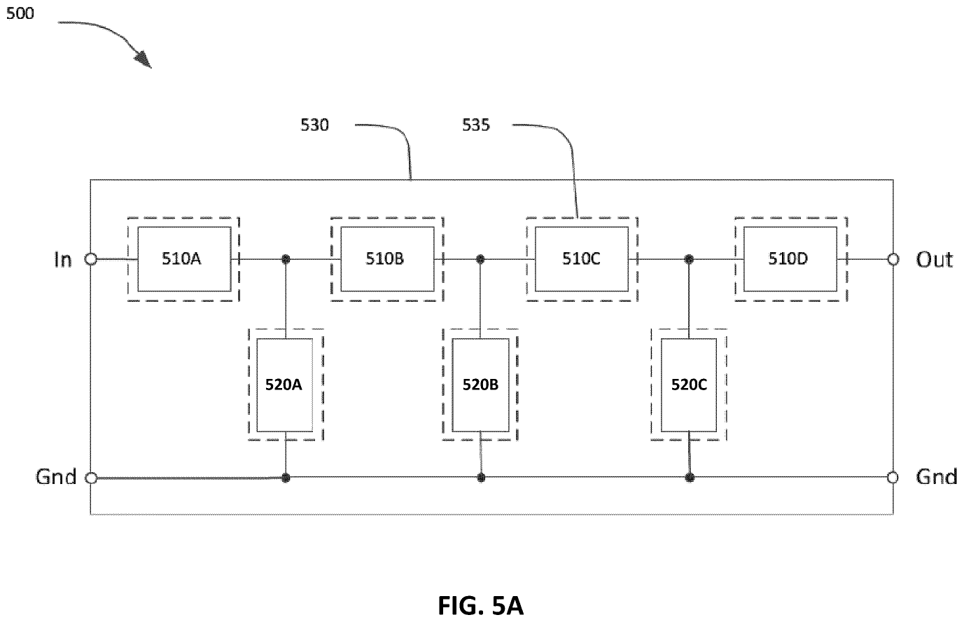

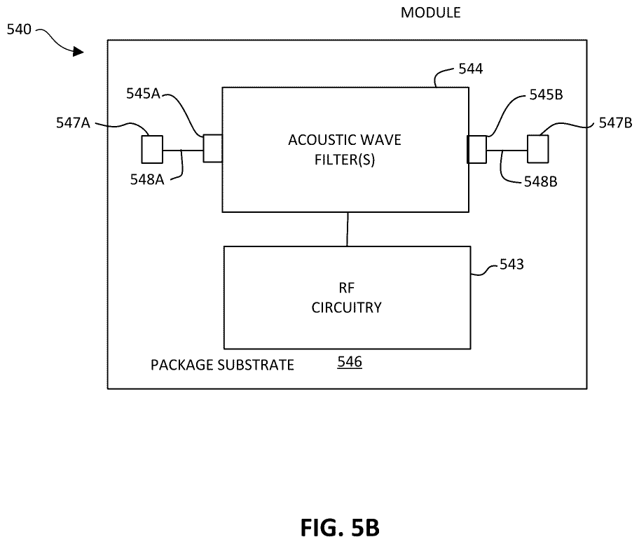

FIG. 5A is a schematic circuit diagram and layout for a high frequency bandpass filter 500 using a plurality of bulk acoustic wave resonators (e.g., XBARs), such as the general XBAR configuration 100 (e.g., the bulk acoustic resonators) described above, for example. The filter 500 has a conventional ladder filter architecture, which may include a split-ladder filter architecture wherein the filter is split between multiple chips, which has a plurality of bulk acoustic resonators including four resonators 510A, 510B, 510C, and 510D and three shunt resonators 520A, 520B and 520C. The series resonators 510A, 510B, 510C and 510D are connected in series between a first port and a second port (hence the term “series resonator”). In FIG. 5A, the first and second ports are labeled “In” and “Out”, respectively. However, the filter 500 is bidirectional and either port may serve as the input or output of the filter. At least two shunt resonators, such as the shunt resonators 520A and 520B, are connected from nodes between series resonators to a ground connection. A filter may contain additional reactive components, such as inductors, not shown in FIG. 5A. All the shunt resonators and series resonators are XBARs (e.g., either of the XBAR configurations 100 and/or 100′ as discussed above) in the exemplary aspect. The inclusion of three series and two shunt resonators is an example. A filter may have more or fewer than five total resonators, more or fewer than three series resonators, and more or fewer than two shunt resonators. Typically, for a split ladder and non-split-ladder filter architectures, all of the series resonators are connected in series between an input and an output of the filter, and all of the shunt resonators are typically connected between ground and the input, the output, or a node between two series resonators.

In the exemplary filter 500, the series resonators 510A, 510B, 510C and 510D and the shunt resonators 520A, 520B and 520C of the filter 500 can be formed on at least one, and in some cases a single, piezoelectric layer 530 of piezoelectric material bonded to a silicon substrate (not visible). However, in alternative aspects, the individual resonators may each be formed on a separate respective piezoelectric layer for each resonator wherein all resonators are located on the same chip. In some cases, however different resonators of a filter may be bonded to a separate substrate, for example. This may result in a split-ladder architecture that can include one or a plurality of separate chips that include separate piezoelectric layers and IDTs of one or more bulk acoustic resonators that are then configured together to form the overall split ladder filter. Moreover, each resonator includes a respective IDT (not shown), with at least the fingers of the IDT disposed over a cavity, or an acoustic mirror, in the substrate. In this and similar contexts, the term “respective” means “relating things each to each,” which is to say with a one-to-one correspondence. In FIG. 5A, the cavities are illustrated schematically as the dashed rectangles (such as the rectangle 535). In this example, each IDT is disposed over a respective cavity. In other filters, the IDTs of two or more resonators may be disposed over a single cavity.

Each of the resonators 510A, 510B, 510C, 510D, 520A, 520B and 520C in the filter 500 has a resonance where the admittance (also interchangeably referred to as Y-parameter) of the resonator is very high and an anti-resonance where the admittance of the resonator is very low. The resonance and anti-resonance occur at a resonance frequency and an anti-resonance frequency, respectively, which may be the same or different for the various resonators in the filter 500. In simplified terms, each resonator can be considered a short-circuit at its resonance frequency and an open circuit at its anti-resonance frequency. The input-output transfer function will be near zero at the resonance frequencies of the shunt resonators and at the anti-resonance frequencies of the series resonators. In a typical filter, the resonance frequencies of the shunt resonators are positioned below the lower edge of the filter's passband and the anti-resonance frequencies of the series resonators are positioned above the upper edge of the passband.

The frequency range between resonance and anti-resonance frequencies of a resonator corresponds to the coupling of the resonator. Depending on the design parameters of the filter 500, each of the resonators 510A, 510B, 510C, 510D, 520A, 520B and 520C may have a particular coupling parameter to which the respective resonator is tuned in order to achieve the required frequency response of the filter 500. According to an exemplary aspect, at least one and/or each of the series resonators 510A, 510B, 510C and 510D and the shunt resonators 520A, 520B and 520C can have an XBAR configuration as described above with respect to FIGS. 1A-2D and 3A-3B in which a diaphragm with IDT fingers spans over a cavity. Alternatively, at least one and/or each of the series resonators 510A, 510B, 510C and 510D and the shunt resonators 520A, 520B and 520C can have an XBAR configuration as described above with respect to FIG. 2E having a solidly-mounted XBAR configuration.

FIG. 5B is a schematic diagram of a radio frequency module that includes an acoustic wave filter device according to an exemplary aspect. In particular, FIG. 5B illustrate a radio frequency module 540 that includes one or more acoustic wave filters 544 according to an exemplary aspect. The illustrated radio frequency module 540 also includes radio frequency (RF) circuitry (or RF circuit) 543. In an exemplary aspect, the acoustic wave filters 544 may include one or more of filter 500 including XBARs (e.g., the bulk acoustic resonators described herein), as described above with respect to FIG. 5A.

The acoustic wave filter 544 shown in FIG. 5B includes terminals 545A and 545B (e.g., first and second terminals). The terminals 545A and 545B can serve, for example, as an input contact and an output contact for the acoustic wave filter 544. Although two terminals are illustrated, any suitable number of terminals can be implemented for a particular application. The acoustic wave filter 544 and the RF circuitry 543 are on a package substrate 546 (e.g., a common substrate) in FIG. 5B. The package substrate 546 can be a laminate substrate. The terminals 545A and 545B can be electrically connected to contacts 547A and 547B, respectively, on the package substrate 546 by way of electrical connectors 548A and 548B, respectively. The electrical connectors 548A and 548B can be bumps or wire bonds, for example. In an exemplary aspect, the acoustic wave filter 544 and the RF circuitry 543 may be enclosed together within a common package, with or without using the package substrate 546.

The RF circuitry 543 can include any suitable RF circuitry. For example, the RF circuitry can include one or more radio frequency amplifiers (e.g., one or more power amplifiers and/or one or more low noise amplifiers), one or more radio frequency switches, one or more additional RF filters, one or more RF couplers, one or more delay lines, one or more phase shifters, or any suitable combination thereof. The RF circuitry 543 can be electrically connected to the one or more acoustic wave filters 544. The radio frequency module 540 can include one or more packaging structures to, for example, provide protection and/or facilitate easier handling of the radio frequency module 540. Such a packaging structure can include an overmold structure formed over the package substrate 546. The overmold structure can encapsulate some or all of the components of the radio frequency module 540.

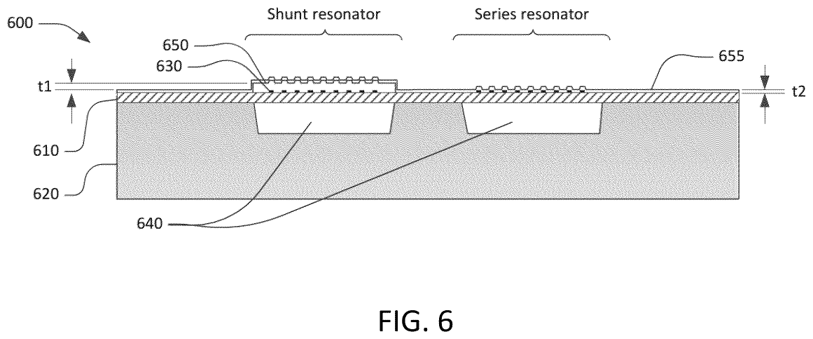

FIG. 6 is a schematic cross-sectional view through a shunt resonator and a series resonator of a filter 600 that uses a dielectric frequency setting layer to separate the resonance frequencies of shunt and series resonators. As shown, a piezoelectric layer 610 is attached to a substrate 620. Portions of the piezoelectric layer 610 form diaphragms that are over cavities 640 in the substrate 620. In an exemplary aspect, a single piezoelectric layer 610 is shown in FIG. 6, which spans multiple cavities 640. In another exemplary aspect, a plurality of separate piezoelectric layers can each span a respective cavity 640. The piezoelectric layer 610 can correspond to the piezoelectric layer 110, as described above, for example.

In either event, interleaved IDT fingers, such as finger 630, are formed on the diaphragms. The interleaved IDT fingers 630 can correspond to fingers 136, 238a, 238b, for example, and while the interleaved IDT fingers 630 are shown to be on a surface of the piezoelectric plate 610 opposite cavities 640, in an alternative aspect the interleaved IDT fingers 630 can be disposed on a surface of the piezoelectric plate 610 facing the cavities 640.

In either case, a first dielectric layer 650, having a thickness t1, is formed over the IDT of the shunt resonator. The first dielectric layer 650 can be considered a “frequency setting dielectric layer,” which is a layer of dielectric material applied to a first subset of the resonators in a filter to offset the resonance frequencies of the first subset of resonators with respect to the resonance frequencies of resonators that do not receive the frequency setting dielectric layer. The frequency setting dielectric layer is commonly silicon dioxide (i.e., SiO₂), but may be silicon oxide, silicon nitride, aluminum oxide, aluminum nitride, beryllium oxide, tantalum oxide, tungsten oxide, or some other dielectric material. The frequency setting dielectric layer may be a laminate or composite of two or more dielectric materials.

A second dielectric layer 655, having a thickness t2, may be deposited over both the shunt and series resonators. The second dielectric layer 655 serves to seal and passivate the surface of the filter 600. The second dielectric layer may be the same material as the first dielectric layer or a different material. The second dielectric layer may be a laminate or composite of two or more different dielectric materials. Further, as will be described subsequently, the thickness of the second dielectric layer may be locally adjusted to fine-tune the frequency of the filter 600. Thus, the second dielectric layer can be referred to as the “passivation and tuning layer.”

The resonance frequency of an XBAR is roughly proportional to the inverse of the total thickness of the diaphragm including the piezoelectric layer 610 and the dielectric layers 650, 655. That is, thinner XBARs will have higher resonant frequencies than thicker XBARs that otherwise have the same configuration. The diaphragm (or the overall stack) of the shunt resonator is thicker than the diaphragm (or the overall stack) of the series resonator by the thickness t1 of the dielectric frequency setting layer 650. Thus, the shunt resonator will have a lower resonance frequency than the series resonator. The difference in resonance frequency between series and shunt resonators is determined by the thickness t1.

In addition to adjusting for a desired resonance frequency, the coupling of each resonator in a filter may also be adjusted to achieve specified performance of the filter. As described above, resonance characteristics may be adjusted by selecting appropriate thicknesses of the first and second dielectric layers. Other parameters, such as crystal cut, pitch of the IDT fingers, and mark of the IDT fingers may also be used to affect both resonance frequency and coupling.

However, because the above-described resonator parameters affect both resonance frequency and coupling, as well as spur location and amplitude, independent tuning of the coupling of a resonator is difficult because other properties of the resonator are often also changed simultaneously. In some related systems and resonator configurations, a capacitor connected in parallel with each resonator may be used to independently adjust or reduce coupling. Such capacitors may be interdigitated capacitors or Metal-Insulator-Metal (MIM) capacitors, both of which may take up additional space on a die. Accordingly, there is a need for a structural variable that may be used to independently tune resonator coupling without consuming additional space on a die.

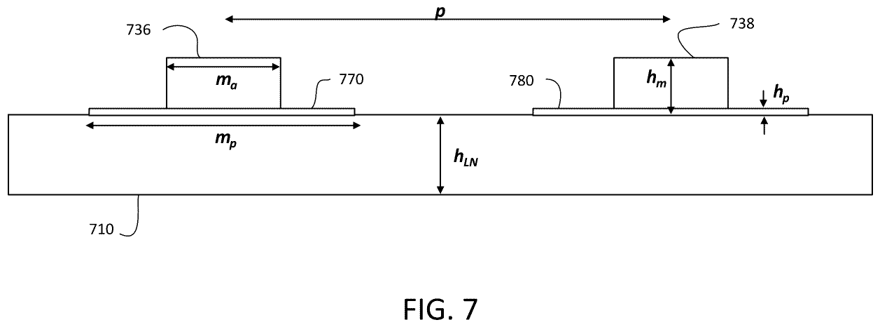

To achieve such independent tuning, FIG. 7 shows an exemplary aspect in which thin metal layers, also called “pedestal-like layers” herein, are formed between the IDT fingers and the piezoelectric layer. In an exemplary aspect, the thin metal pedestal-like layers have a thickness that is, for example, ten percent (i.e., 10%) or less (e.g., 20 nm or less) a thickness of the piezoelectric layer 710. By further adjusting the ratio of the width of the pedestal-like metal layers to the pitch of the IDT fingers, the coupling of the resonator may be changed (e.g., reduced) while minimizing changes to other resonator properties, including the acoustics of the resonator. Yet further, the thickness of the pedestal-like metal layer in the thickness direction are preferably less than one third the thickness of the IDT finger in the thickness direction to also enable the independent control of the resonator's coupling without affecting the acoustics of the resonator.

According to the exemplary aspect, FIG. 7 shows the piezoelectric layer 710 and IDT fingers 736 and 738 supported thereon. In an exemplary aspect, the piezoelectric layer 710 may be a lithium niobate plate having Euler angles that are [0, 30, 0], for example. Between the piezoelectric layer 710 and each of the IDT fingers 736, 738, there is a corresponding thin metal pedestal-like layer (e.g., a metal layer). That is, corresponding pedestal-like metal layer 770 is between IDT finger 736 and the piezoelectric layer 710 and corresponding pedestal-like metal layer 780 is between IDT finger 738 and the piezoelectric layer 710. While the exemplary aspect of FIG. 7 shows two pedestal-like layers, there may be at least one pedestal-like layer between the piezoelectric layer 710 and the IDT fingers. In the exemplary aspect, pedestal-like layer 770 is centered symmetrically with respect to its corresponding IDT finger 736, such that IDT finger 736 is positioned centrally in the width direction with respect to pedestal-like layer 770. In other words, portions of pedestal-like layer 770 that extend beyond the two opposing sides of IDT finger 736 in the width direction (i.e., parallel to the surface of the piezoelectric layer 710) are equal in length on both sides (i.e., opposing sides to the left and right of the IDT finger 736). Likewise, IDT finger 738 is positioned centrally in the width direction with respect to its corresponding pedestal-like layer 780. Other IDT fingers (not shown) supported by piezoelectric layer 710 may likewise have corresponding pedestal-like layers positioned between each IDT finger and the piezoelectric layer 710.

While the exemplary aspect of FIG. 7 shows the IDT fingers 736 and 738 centered (e.g., symmetrically aligned in the vertical direction) with respect to their respective pedestal-like layers 770 and 780, other aspects may include a non-symmetric arrangement of an IDT finger and pedestal-like layer. For example, one or more of the IDT fingers may be positioned closer to one outer edge (e.g., offset in the horizontal direction) and farther from another outer edge of their respective pedestal-like layers. In such aspects, the outer edges of the IDT fingers are located within the outer edges of their respective pedestal-like layers in a plan view. The offset in vertical alignment between the IDT fingers and the pedestal layer could be by design choice or due to misalignment from a manufacturing variance, for example.

It should be appreciated that piezoelectric layer 710 can correspond generally to piezoelectric layer 110, 310, 410, and/or 610 as described above. Similarly, IDT fingers 736 and 738 can correspond to IDT fingers 136 of FIG. 1A, IDT fingers 238a and 238b of FIGS. 2A to 2E, and/or IDT fingers 430 of FIG. 4, for example. However, according to the exemplary aspect of FIG. 7, additional pedestal-like layers (e.g., at least one metal layer) can be disposed between the one or more piezoelectric layers and each respective IDT finger. Moreover, FIG. 7 illustrates a close-up view of only the diaphragm and IDT fingers, and it should be appreciated that such configuration can be implemented with the IDT fingers facing towards (e.g., FIG. 2B) or away (e.g., FIG. 2A) from the respective cavities. Alternatively, this configuration of FIG. 7 can be implemented in an SM XBAR as shown in FIG. 5B and described above, for example. That is, one or more pedestal-like layers may be disposed between the one or more piezoelectric layers and respective IDT fingers in the Bragg mirror arrangement of the SM XBAR configuration described with reference to FIG. 5B.

Moreover, in an exemplary aspect, the IDT fingers 736, 738 are formed of aluminum and the pedestal-like layers 770, 780 are formed of titanium. In other exemplary aspects, different conductive materials may be used to form the IDT fingers 736, 738 and the pedestal-like layers 770, 780. The IDT fingers 736, 738 and the pedestal-like layers 770, 780 may be formed of the same material or formed of different materials. For example, in one aspect, each IDT finger and its corresponding pedestal-like layer may be a single continuous material formed by a photoresist and etching, for example.

In an exemplary aspect, each of the pedestal-like layers 770, 780 may be formed of a plurality of layers of the same or different metals. For example, each pedestal-like layer may be formed of an upper layer closer to the respective IDT finger and having a high adhesion property to the IDT finger and a lower layer closer to the piezoelectric layer and having a higher conductivity property than the upper layer. That is, the upper layer may have a higher adhesion to the respective IDT finger than the lower layer and the lower layer may have a higher conductivity than the upper layer. In an exemplary aspect, in the case that the IDT fingers are formed of aluminum, the upper layer of each of the pedestal-like layers may also be formed of aluminum to achieve higher conductivity to the IDT fingers and the lower layer may be formed of titanium for a higher adhesion property (e.g., to be coupled/adhered to the piezoelectric layer). It is again noted that while the lower layer is formed by a thin (relative to the total thickness of the conductors) layer of titanium in an exemplary aspect, other metals, such as chromium, may also be used together with or in place of titanium to improve adhesion between the fingers and the piezoelectric layer.

In FIG. 7, the center-to-center distance between the IDT fingers 736 and 738 is shown as the pitch p, the width/mark of the IDT fingers is shown as mₐ, and the height/thickness of the piezoelectric layer 710 is shown as h_{LN}. As noted above, in an exemplary aspect, the thin metal pedestal-like layers 770 and 780 can have a thickness that is, for example, ten percent (i.e., 10%) or less (e.g., 20 nm or less) h_{LN} than the thickness of the piezoelectric layer 710 to minimize affects on the acoustics of the resonator. Moreover, the width/mark of the pedestal-like layers 770, 780 is shown as mₚ, the height/thickness of the electrode structure that includes the IDT finger and the pedestal-like layer is shown as hₘ, and the height/thickness of the pedestal-like layer is hₚ.

As shown in FIG. 7, thicknesses (or heights) are measured in a direction perpendicular or normal (i.e., the height or thickness direction) to the surface of the piezoelectric layer 710 that supports the IDT fingers. Widths (or marks) and the pitch of the IDT fingers are measured in a direction parallel (i.e., the width direction) to the surface of the piezoelectric layer 710 that on which the IDT fingers are disposed. In an exemplary aspect, the height/thickness hₚ of the metal layer 770 (and/or 780) in the thickness direction is less than one third (e.g., less than 33%) the thickness hₘ of the finger 736 (and/or 738) in the thickness direction. Effectively, the acoustic resonator utilizes one or more very thin metal layer that are essentially configured as electrical capacitors to independently control the coupling of the resonator without affecting the acoustics of the resonator.

When the width of the pedestal-like layers 770, 780 is equal to the width of the IDT fingers 736, 738, mₚ is equal to mₐ, and there is less of an effect on coupling. In this case, the IDT fingers 736, 738 are merely raised by the pedestal-like layers without any changes in width. On the other hand, when the width of the pedestal-like layers 770, 780 is increased to the point that adjacent pedestal-like layers are almost in contact with each other, the ratio of mₚ to the pitch p approaches 1.0 and the coupling is reduced to zero.

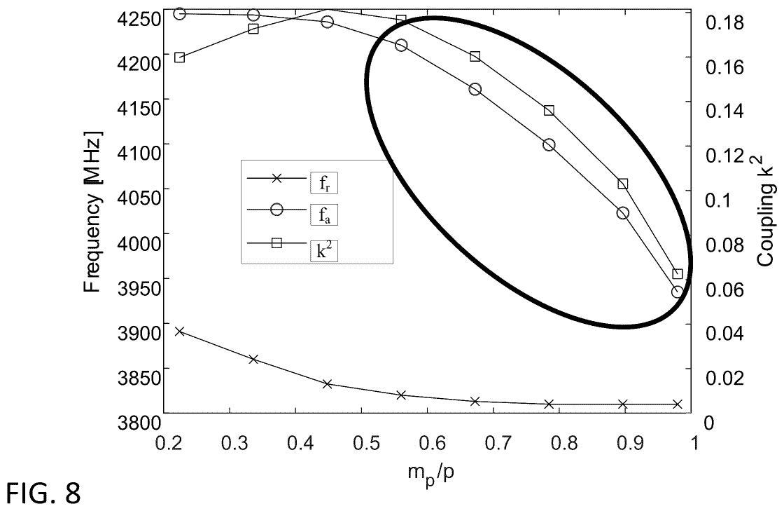

Certain values of the width of the pedestal-like layers mₚ between the above-described lower limit of mₐ and upper limit of p correspond to various coupling parameters of the resonator, as shown in FIG. 8. FIG. 8 graphs simulated resonance frequency values (fᵣ), anti-resonance frequency values (fₐ), and coupling values (k²) on the ordinate (y) axis against the ratio of the width of the pedestal-like layers to the pitch (mₚ/p) on the abscissa (x) axis. The data for FIG. 8 and all subsequent graphs results from simulation of exemplary XBAR devices using a finite element three-dimensional simulation technique.

The fᵣ, fₐ, and k² values shown in FIG. 8 were generated by simulating a resonator formed on a 120Y piezoelectric layer that has a thickness of 350 nm. The simulated resonator has thickness hₘ of the electrode structure that includes the IDT finger and the pedestal-like layer of 385 nm, a pitch of the IDT fingers of 3.4 μm, and a mark of the IDT fingers of 0.76 μm. The simulated resonator also had a front-side dielectric layer with a thickness of 66 nm.

Values of fᵣ and fₐ are defined on the left-hand side axis of the graph of FIG. 8 as frequency in MHz, while values of k² are defined on the right-hand side axis of the graph. The coupling values k² are calculated as a function of the resonance and anti-resonance values according to k²=1−fᵣ²/fₐ².

As highlighted by the oval in FIG. 8, a reduction in coupling values occurs as values of the ratio of the width of the pedestal-like layers to the pitch (mₚ/p) increase between values of 0.45 and 1.0. The decrease in coupling values is caused by a corresponding decrease in the anti-resonance frequency values fₐ, as shown in FIG. 8. On the other hand, the resonance values fᵣ remain substantially constant in the range of values 0.45 to 1.0 of the ratio of the width of the pedestal-like layers to the pitch (mₚ/p).

Accordingly, using the relationship between the ratio of the width of the pedestal-like layers to the pitch (mₚ/p) and the coupling values, as shown in FIG. 8, resonance coupling may be tuned within the value range between 0.18 and 0.07 by selecting an appropriate width mₚ of the pedestal-like layers, assuming a predetermined pitch p of the IDT fingers. That is, as long as the ratio of the width of the pedestal-like layers to the pitch (mₚ/p) is greater than or equal to 0.45, the width of the pedestal-like layers may be adjusted to tune the resonance coupling to a desired (e.g., predetermined) coupling for the acoustic resonator without affecting the resonance frequency.

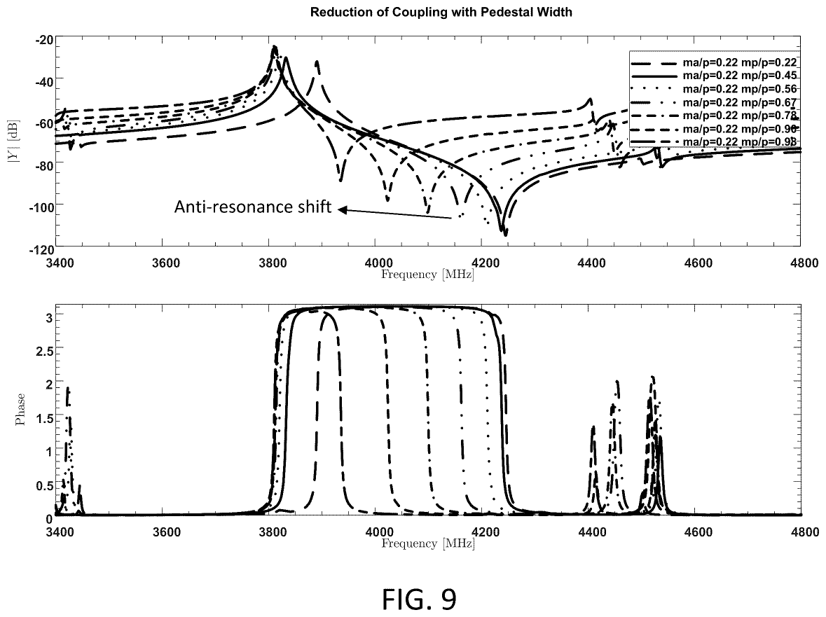

FIG. 9 shows additional graphs showing the shift in anti-resonance frequency that occurs when the ratio of the width of the pedestal-like layers to the pitch (mₚ/p) is adjusted within the range of values between 0.45 and 1. As shown in FIG. 9, the resonance frequency at which an admittance peak occurs is substantially unchanged at 3800 MHz across all curves. That is, the changed ratio mₚ/p for each of the curves of FIG. 9 does not affect the resonance frequency.

On the other hand, the anti-resonance frequency at which admittance is low can be seen to shift down from 4250 MHz to about 3950 MHz across the curves representing different ratios mₚ/p equal to or greater than 0.45. The dashed-line curve representing a ratio mₚ/p of 0.22, which is not above 0.45, can be seen in FIG. 9 as having a moderate shift in resonance frequency and no change in anti-resonance frequency with respect to the solid-line curve representing a ratio mₚ/p of 0.45.

Accordingly, FIG. 9 shows that values of the ratio mₚ/p below 0.45 do not allow for independent tuning of coupling without affecting the resonance frequency. On the contrary, FIG. 9 shows that the resonance frequency shifts with a ratio mₚ/p of 0.22 but maintains a constant value for values of mₚ/p that are equal to or greater than 0.45.

Exemplary aspects of the present disclosure may combine adjustment of the width of the pedestal-like layers with other resonator parameters to optimize coupling characteristics across multiple modes. For example, coupling of S2 and A3 modes may be minimized by selecting thickness values of the front-side and back-side dielectric layers. However, the selected thickness values of the dielectric values may cause A1 mode coupling to be too high to meet filter design parameters.

In such a case, the width of the pedestal-like layers may be adjusted to lower the A1 mode coupling into an acceptable range, while retaining the minimized coupling of S2 and A3 modes achieved by the selected thickness values of the front-side and back-side dielectric layers. In other scenarios, other resonator parameters, such as crystal cut, IDT finger pitch, or IDT finger mark may be optimized for various resonator characteristics in a way that causes coupling to be out of range for the filter design. In such cases, width of the pedestal-like layers may be used as an independent tuning parameter to adjust coupling without affecting the resonance frequency.

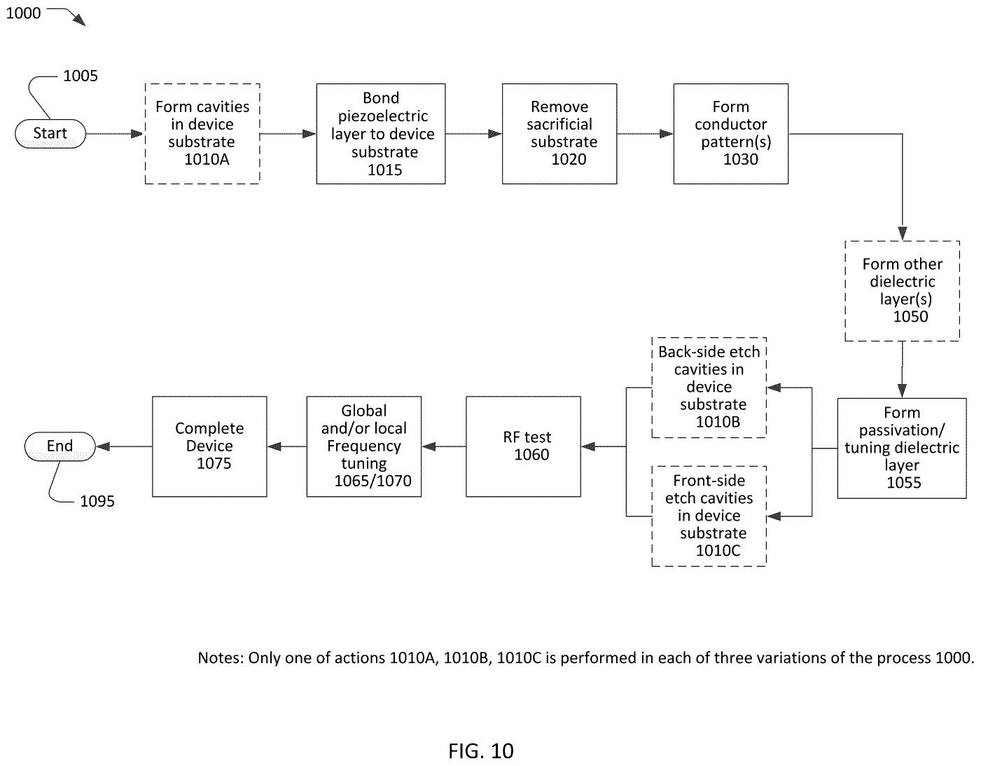

FIG. 10 is a simplified flow chart summarizing a process 1000 for fabricating a filter device incorporating XBARs. Specifically, the process 1000 is for fabricating a filter device including multiple XBARs, some of which may include the pedestal-like layers described above. The process 1000 starts at 1005 with a device substrate and a thin layer of piezoelectric material disposed on a sacrificial substrate. The process 1000 ends at 1095 with a completed filter device. The flow chart of FIG. 10 includes only major process steps. Various conventional process steps (e.g., surface preparation, cleaning, inspection, baking, annealing, monitoring, testing, etc.) may be performed before, between, after, and during the steps shown in FIG. 10.

While FIG. 10 generally describes a process for fabricating a single filter device, multiple filter devices may be fabricated simultaneously on a common wafer (consisting of a piezoelectric layer bonded to a substrate). In this case, each step of the process 1000 may be performed concurrently on all of the filter devices on the wafer.

The flow chart of FIG. 10 captures three variations of the process 1000 for making an XBAR which differ in when and how cavities are formed in the device substrate. The cavities may be formed at steps 1010A, 1010B, or 1010C. Only one of these steps is performed in each of the three variations of the process 1000. In another variation of the process 1000, a solidly mounted XBAR may be fabricated without forming any cavities in the device substrate. An example of a solidly mounted XBAR was described above with reference to FIG. 2E.

The piezoelectric layer may be, for example, a lithium niobate plate or a lithium tantalate plate, either of which may be Z-cut, rotated Z-cut, Y-cut, rotated Y-cut, or rotated YX-cut. For historical reasons, a rotated Y-cut plate configuration may be commonly referred to as “Y-cut”, where the “cut angle” is the angle between the y axis and the normal to the plate. The “cut angle” is equal to β+90°. For example, a plate with Euler angles [0°, 30°, 0°] is commonly referred to as “120° rotated Y-cut”. In some embodiments, the piezoelectric layer's z axis may be normal to the plate surface and the y axis orthogonal to the IDT fingers. Such piezoelectric plates have Euler angles of 0, 0, 90°. Further embodiments may include a piezoelectric layer with Euler angles 0, β, 90°, where B is in the range from −15° to +5°, 0°≤β≤60, or any combination thereof. The piezoelectric layer may be some other material and/or some other cut. The device substrate may preferably be silicon. The device substrate may be some other material that allows formation of deep cavities by etching or other processing.

In one variation of the process 1000, one or more cavities are formed in the device substrate at 1010A, before the piezoelectric layer is bonded to the substrate at 1015. A separate cavity may be formed for each resonator in a filter device. The one or more cavities may be formed using conventional photolithographic and etching techniques. Typically, the cavities formed at 1010A will not penetrate through the device substrate. As described above, the cavities may be in a base, such as silicon, of the substrate. Alternatively, the cavities may be in an intermediate layer, such as silicon dioxide, of the substrate.

At 1015, the piezoelectric layer is bonded to the device substrate. The piezoelectric layer and the device substrate may be bonded by a wafer bonding process. Typically, the mating surfaces of the device substrate and the piezoelectric layer are highly polished. One or more layers of intermediate materials, such as an oxide or metal, may be formed or deposited on the mating surface of one or both of the piezoelectric layer and the device substrate. One or both mating surfaces may be activated using, for example, a plasma process. The mating surfaces may then be pressed together with considerable force to establish molecular bonds between the piezoelectric layer and the device substrate or intermediate material layers.

At 1020, the sacrificial substrate may be removed. For example, the piezoelectric layer and the sacrificial substrate may be a wafer of piezoelectric material that has been ion implanted to create defects in the crystal structure along a plane that defines a boundary between what will become the piezoelectric layer and the sacrificial substrate. At 1020, the wafer may be split along the defect plane, for example by thermal shock, detaching the sacrificial substrate and leaving the piezoelectric layer bonded to the device substrate. The exposed surface of the piezoelectric layer may be polished or processed in some manner after the sacrificial substrate is detached.

Thin layers of single-crystal piezoelectric materials laminated to a non-piezoelectric substrate are commercially available. At the time of this application, both lithium niobate and lithium tantalate layers are available bonded to various substrates including silicon, quartz, and fused silica. Thin layers of other piezoelectric materials may be available now or in the future. The thickness of the piezoelectric layer may be between 300 nm and 1000 nm. When the substrate is silicon, a layer of SiO₂ may be disposed between the piezoelectric layer and the substrate. When a commercially available piezoelectric layer/device substrate laminate is used, steps 1010A, 1015, and 1020 of the process 1000 are not performed.

A first conductor pattern, including IDTs and pedestal-like metal layers of each XBAR, is formed at 1030 by depositing and patterning one or more conductor layers on the front side of the piezoelectric layer. The conductor layer may be, for example, aluminum, an aluminum alloy, copper, a copper alloy, or some other conductive metal. One or more layers of other materials may be disposed below (i.e., between the conductor layer and the piezoelectric layer) and/or on top of the conductor layer. For example, a thin film of titanium, chrome, or other metal may be used to improve the adhesion between the conductor layer and the piezoelectric layer and/or to serve as the pedestal-like metal layers described above. A second conductor pattern of gold, aluminum, copper or other higher conductivity metal may be formed over portions of the first conductor pattern (for example the IDT bus bars and interconnections between the IDTs).

Each conductor pattern may be formed at 1030 by depositing the conductor layer and, optionally, one or more other metal layers in sequence over the surface of the piezoelectric layer. The excess metal may then be removed by etching through patterned photoresist. The conductor layer can be etched, for example, by plasma etching, reactive ion etching, wet chemical etching, or other etching techniques.

Alternatively, each conductor pattern may be formed at 1030 using a lift-off process. Photoresist may be deposited over the piezoelectric layer. and patterned to define the conductor pattern. The conductor layer and, optionally, one or more other layers may be deposited in sequence over the surface of the piezoelectric layer. The photoresist may then be removed, which removes the excess material, leaving the conductor pattern. In either case, the conductor pattern can be formed to include the grating elements as described herein.

At 1050, one or more frequency setting dielectric layer(s) may be formed by depositing one or more layers of dielectric material on the front side of the piezoelectric layer. For example, a dielectric layer may be formed over the shunt resonators to lower the frequencies of the shunt resonators relative to the frequencies of the series resonators. The one or more dielectric layers may be deposited using a conventional deposition technique such as physical vapor deposition, atomic layer deposition, chemical vapor deposition, or some other method. One or more lithography processes (using photomasks) may be used to limit the deposition of the dielectric layers to selected areas of the piezoelectric layer. For example, a mask may be used to limit a dielectric layer to cover only the shunt resonators.

At 1055, a passivation/tuning dielectric layer may be deposited over the piezoelectric layer and conductor patterns. The passivation/tuning dielectric layer may cover the entire surface of the filter except for pads for electrical connections to circuitry external to the filter. In some instantiations of the process 1000, the passivation/tuning dielectric layer may be formed after the cavities in the base of the device substrate and/or intermediate layer of the substrate are etched at either 1010B or 1010C.

In a second variation of the process 1000, one or more cavities are formed in the back surface of the base of the device substrate and/or the intermediate layer of the substrate at 1010B. A separate cavity may be formed for each resonator in a filter device. The one or more cavities may be formed using an anisotropic or orientation-dependent dry or wet etch to open holes through the back side of the device substrate to the piezoelectric layer. In this case, the resulting resonator devices will have a cross-section as shown in FIG. 1.

In a third variation of the process 1000, one or more cavities in the form of recesses in the device substrate may be formed at 1010C by etching the substrate using an etchant introduced through openings in the piezoelectric layer. A separate cavity may be formed for each resonator in a filter device. The one or more cavities formed at 1010C will not penetrate through the device substrate.

Ideally, after the cavities are formed at 1010B or 1010C, most or all of the filter devices on a wafer will meet a set of performance requirements. However, normal process tolerances will result in variations in parameters such as the thicknesses of dielectric layer formed at 1050 and 1055, variations in the thickness and line widths of conductors and IDT fingers formed at 1030, and variations in the thickness of the piezoelectric layer. These variations contribute to deviations of the filter device performance from the set of performance requirements.

To improve the yield of filter devices meeting the performance requirements, frequency tuning may be performed by selectively adjusting the thickness of the passivation/tuning layer deposited over the resonators at 1055. The frequency of a filter device passband can be lowered by adding material to the passivation/tuning layer, and the frequency of the filter device passband can be increased by removing material to the passivation/tuning layer. Typically, the process 1000 is biased to produce filter devices with passbands that are initially lower than a required frequency range but can be tuned to the desired frequency range by removing material from the surface of the passivation/tuning layer.

At 1060, a probe card or other means may be used to make electrical connections with the filter to allow radio frequency (RF) tests and measurements of filter characteristics such as input-output transfer function. Typically, RF measurements are made on all, or a large portion, of the filter devices fabricated simultaneously on a common piezoelectric layer and substrate.

At 1065, global frequency tuning may be performed by removing material from the surface of the passivation/tuning layer using a selective material removal tool such as, for example, a scanning ion mill as previously described. “Global” tuning is performed with a spatial resolution equal to or larger than an individual filter device. The objective of global tuning is to move the passband of each filter device towards a desired frequency range. The test results from 1060 may be processed to generate a global contour map indicating the amount of material to be removed as a function of two-dimensional position on the wafer. The material is then removed in accordance with the contour map using the selective material removal tool.

At 1070, local frequency tuning may be performed in addition to, or instead of, the global frequency tuning performed at 1065. “Local” frequency tuning is performed with a spatial resolution smaller than an individual filter device. The test results from 1060 may be processed to generate a map indicating the amount of material to be removed at each filter device. Local frequency tuning may require the use of a mask to restrict the size of the areas from which material is removed. For example, a first mask may be used to restrict tuning to only shunt resonators, and a second mask may be subsequently used to restrict tuning to only series resonators (or vice versa). This would allow independent tuning of the lower band edge (by tuning shunt resonators) and upper band edge (by tuning series resonators) of the filter devices.

After frequency tuning at 1065 and/or 1070, the filter device is completed at 1075. Actions that may occur at 1075 include forming bonding pads or solder bumps or other means for making connection between the device and external circuitry (if such pads were not formed at 1030); excising individual filter devices from a wafer containing multiple filter devices; other packaging steps; and additional testing. After each filter device is completed, the process ends at 1095.

Throughout this description, the embodiments and examples shown should be considered as examples, rather than limitations on the apparatus and procedures disclosed or claimed. Although many of the examples presented herein involve specific combinations of method acts or system elements, it should be understood that those acts and those elements may be combined in other ways to accomplish the same objectives. With regard to flowcharts, additional and fewer steps may be taken, and the steps as shown may be combined or further refined to achieve the methods described herein. Acts, elements and features discussed only in connection with one embodiment are not intended to be excluded from a similar role in other embodiments.

As used herein, “plurality” means two or more. As used herein, a “set” of items may include one or more of such items. As used herein, whether in the written description or the claims, the terms “comprising”, “including”, “carrying”, “having”, “containing”, “involving”, and the like are to be understood to be open-ended, i.e., to mean including but not limited to. Only the transitional phrases “consisting of” and “consisting essentially of”, respectively, are closed or semi-closed transitional phrases with respect to claims. Use of ordinal terms such as “first”, “second”, “third”, etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements. As used herein, “and/or” means that the listed items are alternatives, but the alternatives also include any combination of the listed items.

What is claimed:

1. An acoustic resonator device comprising:
a piezoelectric layer;
an interdigital transducer (IDT) on a surface of the piezoelectric layer, the IDT including interleaved IDT fingers extending from first and second busbars respectively; and
a metal layer disposed between a finger of the interleaved IDT fingers and the piezoelectric layer in a thickness direction that is measured in a direction normal to the surface of the piezoelectric layer,
wherein a ratio of a width of the metal layer to a pitch of the interleaved IDT fingers is greater than or equal to 0.45, the width of the metal layer being measured in a width direction that is parallel to the surface of the piezoelectric layer, and
wherein a thickness of the metal layer in the thickness direction is less than one third a thickness of the finger in the thickness direction.

2. The acoustic resonator device according to claim 1, further comprising:
a substrate; and
a dielectric layer having a cavity disposed therein,
wherein the piezoelectric layer is on the dielectric layer and includes a portion that forms a diaphragm that is over the cavity in the dielectric layer.

3. The acoustic resonator device according to claim 1, wherein:
the width of the metal layer is greater than a width of each of the interleaved IDT fingers measured in the width direction, and
the finger is positioned centrally in the width direction with respect to the metal layer, such that the metal layer extends beyond two opposing sides of the finger in the width direction.

4. The acoustic resonator device according to claim 1, wherein the thickness of the metal layer in the thickness direction is less than 20 nanometers.

5. The acoustic resonator device according to claim 1, wherein the thickness of the metal layer in the thickness direction is less than 10% of a thickness of the piezoelectric layer in the thickness direction.

6. The acoustic resonator device according to claim 1, wherein:
the metal layer comprises a first metal layer and a second metal layer,
the first metal layer is positioned closer in the thickness direction to the piezoelectric layer than the second metal layer and has a higher conductivity than a conductivity of the second metal layer, and
the second metal layer is in contact with the finger of the interleaved IDT fingers and has a higher adhesion to the finger of the interleaved IDT fingers than the first metal layer.

7. The acoustic resonator device according to claim 6, wherein the first metal layer comprises titanium and the second metal layer comprises aluminum.

8. The acoustic resonator device according to claim 1, wherein the ratio of the width of the metal layer to the pitch of the interleaved IDT fingers is less than 1.0.

9. The acoustic resonator device according to claim 8, wherein the ratio of the width of the metal layer to the pitch of the interleaved IDT fingers is greater than or equal to 0.45 and less than 1.0, the ratio corresponding to a desired coupling between a resonance frequency and an anti-resonance frequency of the acoustic resonator device.

10. The acoustic resonator device of claim 1, wherein the piezoelectric layer is a lithium niobate plate having Euler angles that are [0, 30, 0].

11. The acoustic resonator device of claim 1, wherein the IDT is configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved IDT fingers.

12. A filter device comprising:
a plurality of bulk acoustic wave resonators, with at least one of the plurality of bulk acoustic wave resonators comprising:
a piezoelectric layer;
an interdigital transducer (IDT) on a surface of the piezoelectric layer, the IDT including interleaved IDT fingers extending from first and second busbars respectively; and
a metal layer disposed between a finger of the interleaved IDT fingers and the piezoelectric layer in a thickness direction that is measured in a direction normal to the surface of the piezoelectric layer,
wherein a ratio of a width of the metal layer to a pitch of the interleaved IDT fingers is greater than or equal to 0.45, the width of the metal layer being measured in a width direction that is parallel to the surface of the piezoelectric layer, and
wherein a thickness of the metal layer in the thickness direction is less than one third a thickness of the finger in the thickness direction.

13. The filter device according to claim 12, wherein the at least one bulk acoustic wave resonator further comprises:
a substrate; and
a dielectric layer having a cavity disposed therein,
wherein the piezoelectric layer is on the dielectric layer and includes a portion that forms a diaphragm that is over the cavity in the dielectric layer.

14. The filter device according to claim 12, wherein:
the width of the metal layer is greater than a width of each of the interleaved IDT fingers measured in the width direction, and
the finger is positioned centrally in the width direction with respect to the metal layer, such that the metal layer extends beyond two opposing sides of the finger in the width direction.

15. The filter device according to claim 12, wherein the thickness of the metal layer in the thickness direction is less than 10% of a thickness of the piezoelectric layer in the thickness direction.

16. The filter device according to claim 12, wherein:
the metal layer comprises a first metal layer and a second metal layer,
the first metal layer is positioned closer in the thickness direction to the piezoelectric layer than the second metal layer and has a higher conductivity than a conductivity of the second metal layer, and
the second metal layer is in contact with the finger of the interleaved IDT fingers and has a higher adhesion to the finger of the interleaved IDT fingers than the first metal layer.

17. The filter device according to claim 12, wherein the ratio of the width of the metal layer to the pitch of the interleaved IDT fingers is less than 1.0.

18. The filter device according to claim 17, wherein the ratio of the width of the metal layer to the pitch of the interleaved IDT fingers is greater than or equal to 0.45 and less than 1.0, the ratio corresponding to a desired coupling between a resonance frequency and an anti-resonance frequency of the at least one bulk acoustic resonator.

19. The filter device of claim 12, wherein the IDT is configured such that a radio frequency signal applied to the IDT excites a bulk shear acoustic wave in the piezoelectric layer where acoustic energy propagates along a direction substantially orthogonal to the surface of the piezoelectric layer, which is transverse to a direction of an electric field created by the interleaved IDT fingers.

20. A radio frequency module comprising:
a filter device including a plurality bulk acoustic resonators connected in parallel; and
a radio frequency circuit coupled to the filter device, the filter device and the radio frequency circuit being enclosed within a common package, wherein at least one bulk acoustic resonator of the filter device includes:
a piezoelectric layer;
an interdigital transducer (IDT) on a surface of the piezoelectric layer, the IDT including interleaved IDT fingers extending from first and second busbars respectively; and
a metal layer disposed between a finger of the interleaved IDT fingers and the piezoelectric layer in a thickness direction that is measured in a direction normal to the surface of the piezoelectric layer,
wherein a ratio of a width of the metal layer to a pitch of the interleaved IDT fingers is greater than or equal to 0.45, the width of the metal layer being measured in a width direction that is parallel to the surface of the piezoelectric layer, and
wherein a thickness of the metal layer in the thickness direction is less than one third a thickness of the finger in the thickness direction.
